(19) United States
(12) Patent Application Publication
(10) Pub. No.: US 2003/0064606 A1
(43) Pub. Date: Apr. 3, 2003

(54) Electrically-conductive thermal insulator

(75) Inventor: David L. Hunn, Kennedale, TX (US)

Correspondence Address: SIDLEY AUSTIN BROWN & WOOD LLP, 717 NORTH HARWOOD, SUITE 3400, DALLAS, TX, 75201, US

(73) Assignee: LOCKHEED MARTIN CORPORATION

(21) Appl. No.: 09/966,480

(22) Filed: Sep. 28, 2001

(51) Int. Cl. H01L 21/31; H01L 21/469

(52) U.S. Cl. 438/780; 438/758

(57) ABSTRACT

A low-density electrically-conductive thermal insulator is a coupling of a polymer-based thermally-insulating material with an open-celled electrically-conductive base material defining a plurality of interconnected cells throughout. The open-celled, electrically-conductive base material is preferably an open-celled metallic foam material formed by an interconnected plurality of electrically-conductive ligaments. The electrically-conductive base material may be first formed into a desired shape or structure, coated such that cells in the electrically-conductive base structure are substantially filled with the insulating material, and then cured to solidify the insulating material. The electrically-conductive thermal insulator provides thermal protection while providing electrical conductivity. Further the electrically-conductive thermal insulator of the present invention is adapted to be low density, lightweight, electrically conductive, and to maintain its structural integrity under aerothermal conditions typical of high speed flight.

### FIELD OF THE INVENTION

The present invention relates broadly to thermal insulators. More particularly, the invention relates to an electrically-conductive metal foam thermal insulator suitable for use in high temperature applications and to a method of forming the same.

### BACKGROUND OF THE INVENTION

The exterior panels or skin of a vehicle traveling through the atmosphere at high speeds, such as at supersonic or hypersonic speeds, becomes extremely hot due to aerodynamic heating. The vehicle, for example, a rocket, a missile, an aircraft, or a projectile, generally has a body or shell which houses delicate and heat sensitive electronic equipment, such as guidance and control electronics, which themselves generate heat during operation.

Vehicles adapted for high speed flight must be designed to be aeroelastic, such that they are somewhat flexible, yet retain their desired shape, while withstanding structural and heat loads. At the same time, they must be aerodynamic and lightweight, such that they meet aerodynamic performance criteria. Such vehicles are generally constructed from a combination of materials. For example, a thin sheet of steel, titanium, aluminum, or other metal or an organic composite may be used for exterior portions of the vehicle, e.g., the skin panels, etc., according to the intended flight regime. Materials used for the exterior portions are generally selected to withstand the extreme heat loads of high speed flight. Internal structural components may be formed from aluminum, magnesium, fiberglass, or other strong yet lightweight materials. Many of these materials are not able to withstand such extreme temperatures and would fail if subjected to such extreme heat loads.

In applications where a vehicle must endure harsh aerothermal environments, heat sensitive electronic equipment within the vehicle must be shielded from extreme temperatures to protect its integrity and operability. Further, such equipment must be protected from damage due to lightning strikes which focus an enormous amount of heat and electrical energy in one area of the vehicle. This heat can cause ultimate failure of that portion of the vehicle. The electrical energy will tend to travel through conductive portions of the vehicle, i.e., the electronic equipment, and potentially damage or destroy the electronic equipment. Therefore, in such applications, it is imperative to have a highly electrically-conductive thermally-insulating material which can protect the vehicle from damage due to heat, as well as protect the vehicle from electrical shock of a lightning strike, by conducting the electricity away from the internal equipment. Additionally, some applications integrate antenna elements into the skin of the vehicle and these elements require electrical conductivity for operation. Unfortunately, thermal insulation and electrical conductivity are generally mutually exclusive properties. The vehicle designer is required to find space to both thermally insulate the vehicle and find additional space for inclusion of a method for electrical conduction. This requirement can greatly increase the size, weight, and cost of a vehicle and can potentially require alterations to the aerodynamic shape of the vehicle, thereby adversely affecting the resulting aerodynamic performance of the vehicle. Therefore, it is also imperative that the electrically-conductive thermally-insulating material be moldable to fit into tight spaces as needed, not greatly impact the shape or weight of the vehicle, and be low cost.

A number of types of thermal insulators have been used in such applications. However, they either are expensive or not durable and cannot withstand the thermal loads of high-speed flight. Further, they do not provide both thermal insulation and electrical conductivity. Additionally, they may be too bulky, too heavy, or they do not maintain their structural integrity or thermally insulative properties under the aerothermal conditions of high speed flight or during the highly electrically charged conditions resulting from a lightning strike. For example, thermal insulators such as microballoons, RF capacitive coupling, embedded metallic meshes and fibers, multiple filler-type materials, and plasma spraying of metal coatings directly on silicone have all been tried. Microballoons failed due to thermal expansion of the silicone, pulling the coated spheres apart and breaking the DC path. RF capacitive coupling was found not to be effective at grazing angles and also required a DC path. Embedded metallic meshes and fibers were found to be costly and difficult to manufacture. Multiple other filler type materials such as metal flakes, carbon nanofibers, and metal whiskers were found not to be effective. Plasma spraying of metal coatings directly on silicone was found to be possible. However, the metal coating on the plasma sprayed metal coated silicone was found to be non-durable and is therefore unsuitable for use in high shear environments. Metal foams have been around a long time with applications as low-density/low-cost radiator fillers. However, they have never been adapted to form an electrically-conductive thermal insulator.

What is needed is a highly durable, low density, inexpensive, and easy-to-manufacture thermal insulator which is adaptable for use in the aerothermal conditions of high-speed flight regimes and which is also electrically-conductive to prevent electrical damage to the vehicle and its components resulting from lightning strikes.

### SUMMARY OF THE INVENTION

It is therefore an object of the invention to provide a thermal insulator suitable for use in heat intensive environments.

It is another object of the invention to provide a thermal insulator which is electrically conductive.

It is yet another object of the invention to provide an electrically-conductive thermal insulator which is durable, has a low density, and has a high thermal insulating capacity.

It is yet another object of the invention to provide an electrically-conductive thermal insulator which is easy and inexpensive to manufacture, which can be easily adapted to conform to any shape, and which can be applied in a variety of applications.

In accordance with these objects, which will be discussed in detail below, a durable, low-density, electrically-conductive thermal insulator is provided which is formed as a composite comprising a coupling of a thermally-insulating material with an electrically-conductive base material. Preferably, the thermally-insulating material is a curable polymer-based material which is liquid in an uncured precursor form and which, when cured, can withstand thermal extremes and still maintain its thermally-insulating properties. More preferably, the polymer-based material is a silicone-based material. The electrically-conductive base material defines a plurality of cells or voids throughout. The cells or voids in the electrically-conductive base material reduce the mass, weight and density of the electrically-conductive base material with respect to a solid electrically-conductive base material. Preferably, the plurality of cells are interconnected forming an open-celled electrically-conductive base material. More preferably, the electrically-conductive base material is an open-celled metallic foam.

The electrically-conductive thermal insulator is preferably formed by coating the electrically-conductive base material with a thermally-insulating material precursor, which is fluid under the coating condition, such that the cells or voids within and throughout the electrically-conductive base material are substantially filled with the thermally-insulating material precursor and such that all surfaces of the electrically-conductive base material are substantially coated by the thermally-insulating material precursor. The thermally-insulating material precursor is then cured to form a solid thermally-insulating material throughout and surrounding the electrically-conductive base material, thereby forming a low-density, electrically-conductive thermal insulator of the present invention.

The electrically-conductive thermal insulator of an exemplary embodiment of the present invention provides both thermal protection and electrical conductivity for use in a variety of applications Due to the multi-celled structure of the electrically-conductive base material, the electrically-conductive thermal insulator has a low density, thereby reducing its weight. Further, once the thermally-insulating material precursor is cured, the resulting electrically-conductive thermal insulator is durable and maintains its structural integrity under aerothermal conditions typical of high speed flight. Still further, the electrically-conductive thermal insulator can be formed such that it is substantially rigid, thereby maintaining its shape under loading conditions. Likewise, the electrically-conductive thermal insulator can be formed such that it is somewhat malleable, such that it can be adapted to conform to any of a variety of desired shapes.

The structural, thermally insulative, and electrically-conductive properties of the electrically-conductive thermally-insulating material of the present invention depend upon the properties of the electrically-conductive base material selected, the cell structure of the electrically-conductive base material (i.e., the size and number of cells or voids within the base material and whether or not the cell structure is open or closed), the degree of penetration of the thermally-insulating material precursor within the cell structure of the electrically-conductive base material, and the thickness, durability, and thermal insulating properties of the cured thermally-insulating material.

Additional objects, advantages, and features of the invention will become apparent to those skilled in the art upon reference to the detailed description taken in conjunction with the provided figures, which illustrate a specific embodiment of the invention.

### BRIEF DESCRIPTION OF THE DRAWINGS

FIG. 1 is a cutaway perspective view of a low-density, electrically-conductive thermal insulator in accordance with the present invention;

FIG. 2 is a cross-sectional view of the low-density, electrically-conductive thermal insulator of FIG. 1; and

FIGS. 3A-3C show an exemplary method of forming the low-density, electrically-conductive thermal insulator of FIG. 1 where FIG. 3A shows an exemplary open-celled, electrically-conductive base material;

FIG. 3B shows the open-celled, electrically-conductive base material being coated with a curable polymer-based thermal insulating precursor material, and

FIG. 3C shows an exemplary embodiment of the resulting electrically-conductive thermal insulator.

### DETAILED DESCRIPTION OF THE INVENTION

Referring to FIGS. 1, 2, and 3A-3C, an exemplary embodiment of a low-density electrically-conductive thermal insulator 100 formed as a composite comprising a coupling of an electrically-conductive base material 120 and a thermally-insulating material 110 is shown. According to the embodiment of the present invention, the electrically-conductive base material defines a plurality of cells or voids 122 throughout forming a multi-celled structure. The plurality of cells 122 or voids reduces the density and thereby the weight of the electrically-conductive base material 120 from that of a same size solidly-formed base material formed of the same electrically-conductive material. The cells 122 of the multi-celled structure of the electrically-conductive base material 120 are preferably interconnected, forming an open-celled structure. Preferably, the multi-celled electrically-conductive base material 120 is formed as an open-celled metallic foam. The open-celled metallic foam can be formed from any suitable material including any one of, or a combination of, various electrically-conductive metals or composites including but not limited to aluminum, nickel, iron, copper, or titanium. Preferably, the electrically-conductive base material is formed from aluminum or copper.

The open-celled metallic foam can be formed in any suitable manner. One particular method of forming the open-celled metallic foam is by forming a compilation of interconnected electrically-conductive metallic ligaments or strands (not shown). The size, shape, number and arrangement of the ligaments defines the plurality of cells in the multi-celled structure of the electrically-conductive base material. The ligaments can be of any suitable length and diameter and can be of varying density ranging from substantially hollow to solid. Preferably, the ligaments forming the electrically-conductive base material range in size from about 0.02 inch in diameter to about 0.003 inch in diameter. The small size, arrangement, and density of the ligaments forming the electrically-conductive base material contribute to the reduced weight and reduced density of the open-celled electrically-conductive metallic foam base material 120 compared with other electrically-conductive base materials formed from similarly sized coated solid metals of the prior art.

The multi-celled structure of the electrically-conductive base material 120 can range from substantially rigid to somewhat malleable depending upon the electrically-conductive material or materials selected, the number, size, shape, and arrangement of ligaments forming the base structure (if formed by interconnected ligaments), the size and number of cells or voids throughout the base material, the spacing between the cells, and the degree of interconnectivity of the cells. The more numerous the cells, the lower the density of the electrically-conductive base material and thereby the lower the weight of the base material and potentially, the lower the weight of the final product. Further, the more numerous the cells, the more space provided for the uncured thermally-insulating material precursor to penetrate and flow throughout the cells of the electrically-conductive base material thereby providing better thermal insulation when cured. Preferably the number of the intermittent, interconnected cells 122 of the multi-celled, electrically-conductive material 120 is in the range of about 10 cells to about 40 cells per linear inch. Preferably the multi-celled electrically-conductive base material has a theoretical density in the range of about 3% to about 15% of the density of a similar solid structure formed from the same electrically-conductive material forming the multi-celled electrically-conductive base material of the present invention.

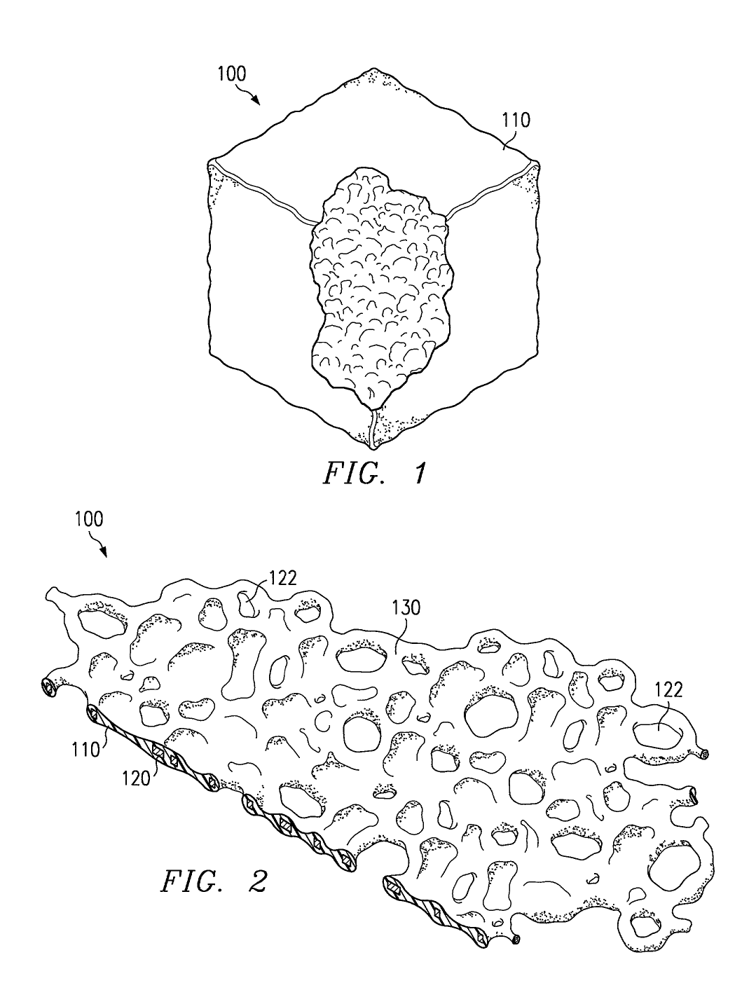

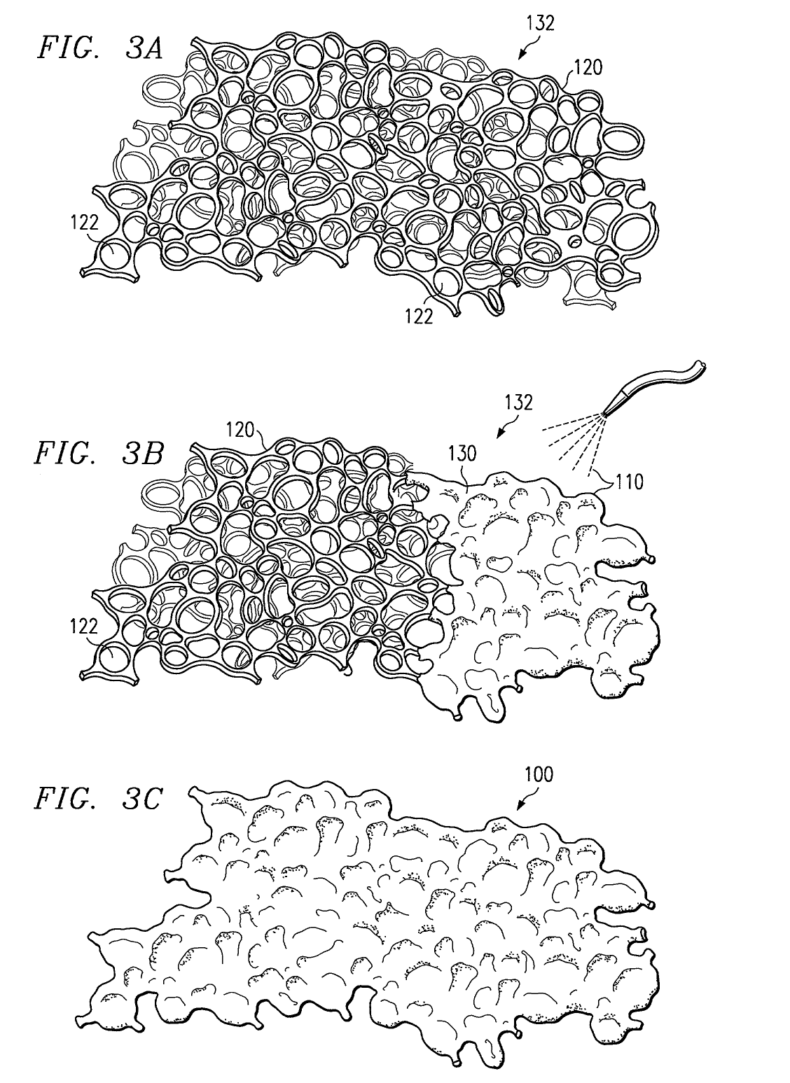

As shown in FIGS. 2 and 3B, the thermally-insulating material 110 can be any one of, or a combination of, a variety of thermally-insulating material precursors which can be cured to a substantially solid state and which, in an uncured state, have a viscosity low enough to flow throughout the plurality of cells 122 in the preferably open-celled structure of the multi-celled electrically-conductive base material 120. Preferably, the curable thermally-insulating material is a polymer-based thermally-insulating material. More preferably, the curable polymer-based thermally-insulating material 110 is formed of a silicone-based elastomer. By way of example and not by way of limitation, exemplary silicone ablators or resins include, but are not limited, to MI-15™ manufactured by Lockheed Martin Corporation, which is a filled elastomeric silicone having an uncured density of 15+/−2 lb/ft3 and having a thermal conductivity when cured of 0.05+/−0.02 Btu/h-ft-F and which is available in either a sprayable or trowelable form; and DC 93-104™ which is a two-component silicone rubber manufactured by Dow Corning with a density of 92+/−10 lb/ft3 and a thermal conductivity when cured of 0.20+/−0.1 Btu/h-ft-F. Other exemplary curable polymer-based thermally insulative materials include, but are not limited, to a phenolic-based polymer; for example, phenol-formaldehyde or phenol-furfural. The polymer-based thermally-insulating material precursor can be cured by heating to a suitable curing temperature to effect thermosetting or it can be chemically cured by action of a curing agent. Prior to curing, the thermally-insulating material precursor can be mixed with glass or ceramic microballoons (not shown) in any suitable amount. Generally, the thermally-insulating material precursor can contain filler material in a range of about 2 volume percent to about 25 volume percent of the total uncured thermally-insulating material precursor. The presence of glass and ceramic filler material within the thermally-insulating material precursor can lower the weight of the cured thermally-insulating material, can reduce the density of the cured thermally-insulating material, and can affect the thermal conductivity of the cured thermally-insulating material.

As described above, it is preferable that the cells 122 of the electrically-conductive base material 120 be substantially interconnected, forming an open-celled structure. As described previously, it is preferable that the curable thermally-insulating material precursor 110 is applied to the electrically-conductive base material 120 such that it thoroughly coats all surfaces throughout the multi-celled, electrically-conductive base material 120. Further, as discussed above and as shown in FIG. 2, it is preferable that the curable thermally-insulating material precursor 110 act as a filler substantially filling the plurality of interconnected cells 122 in the preferably open-celled structure of the electrically-conductive base material 120. While it is preferable and advantageous that the multi-celled structure of the electrically-conductive base material be an open-celled structure and more preferably an open-celled metallic foam, it is understood that other types of materials having similar multi-cellular structure and electrical conductivity properties can be used instead. Therefore, for the sake of clarity and uniformity throughout, the electrically-conductive base material 120 of the present invention will hereinafter be referred to as the multi-celled, electrically conductive base material 120.

Referring now specifically to FIGS. 3A-3C, a method of forming the electrically-conductive thermal insulator 100 is shown. The electrically-conductive thermal insulator 100 of the exemplary embodiment is preferably formed by initially forming the multi-celled, electrically-conductive base material 120 into a desired size, shape, or structure 132 (shown in FIG. 3A). Then, the thermally-insulating material precursor 110 is applied to the multi-celled electrically-conductive base material 120 such that the thermally-insulating material precursor 110 coats or substantially covers all surfaces of a structure 132 formed by the multi-celled, electrically-conductive base material 120. Where the plurality of cells 122 of the multi-celled electrically-conductive base material forming the structure 132 are open and interconnected, it is preferable that the thermally-insulating material 110 impregnates or substantially fills the plurality of interconnected cells 122 in the multi-celled electrically conductive base material 120 (shown in FIG. 3B). By this process, the thermally-insulating material 110 and the multi-celled electrically-conductive base material 120 are substantially interwoven. The thermally-insulating material 110 is then cured, solidifying the thermally-insulating material 110, and thereby forming the electrically-conductive thermal insulator 100 (shown in FIG. 3C). Alternately, it is possible to form the electrically-conductive thermal insulator 100 into a desired shape after the thermally-insulating material 110 has been applied and cured.

The multi-celled electrically-conductive base material 120 forming the structure 132 can be coated with the insulating material 110 by the method of dipping, casting, pouring, immersion, spraying, or any other suitable method. Preferably, the thermally-insulating material 110 is sprayed or cast to the multi-celled, electrically-conductive base material 120. Those skilled in the art will appreciate that various methods of curing could be implemented based on the standard of curing required for the particular thermally-insulating material selected. It will be appreciated by those skilled in the art that particular polymer materials can be cured by heating to a suitable curing temperature to effect thermosetting, or they can be cured by action of a curing agent.

Depending on the malleability of the multi-celled electrically-conductive base material used and the flexibility of the cured thermally-insulating material, the electrically-conductive thermal insulator 100 formed as described above may be bent or molded to conform to a desired shape. Alternately, the multi-celled, electrically-conductive base material may be contoured or pre-molded to conform to a shape of a desired structure and then the thermally-insulating material can be applied and cured. The electrically-conductive thermal insulator formed as described above may also be given a sanded or machined surface finish.

The resulting electrically-conductive thermal insulator 100 is a composite material which is significantly lower in density, lighter in weight, and more durable than prior art electrically-conductive thermal insulators in electrically-conductive aerothermal environments. The electrically-conductive thermal insulator 100 is electrically-conductive due to the electrically-conductive metallic material forming the multi-celled, electrically-conductive base material. An electrically-conductive thermal insulator 100 formed by the above-described method may be designed to achieve any desired electrical conductivity depending on a number of factors, including the electrical conductivity of the material used to form the electrically-conductive base material. However, it is preferable that the electrically-conductive thermal insulator to be used under extreme aerothermal conditions achieves an electrical conductivity in the range of zero to 5 ohms per square at 700° C.

The electrically-conductive thermal insulator 100 formed as described above has been developed for use in applications where it is desirable to insulate an object from heat while simultaneously maintaining electrical conductivity. The resulting electrically-conductive thermal insulator 100 is a composite material which is significantly lower in density, lighter in weight, and more durable than prior art electrically-conductive thermal insulators in electrically-conductive aerothermal environments. The electrically-conductive thermal insulator 100 of the present invention is electrically-conductive due to the electrically-conductive metallic material forming the multi-celled, electrically-conductive base material. The reduction in density is useful for applications where it is desirable to keep the weight of an object to a minimum. The reduced-density properties of the electrically-conductive thermal insulator 100 are achieved by forming the electrically-conductive base material as a multi-celled structure instead of a solid structure of the prior art. This reduces both the weight and density of the electrically-conductive base material. The durability of the thermal insulator is enhanced due to the greater percentage of thermally-insulating material with respect to the electrically conductive material as compared with coated solid core insulative structures of the prior art. As the multi-celled structure of the electrically conductive material of the present invention allows for the insulating material to coat and substantially surround a greater percentage of the electrically-conductive material than would be covered on a solid electrically-conductive material, the thermally-insulating material is able to provide more efficient insulating properties, thereby increasing the durability of the insulating material and the electrically-conductive thermal insulator. The described preferred method also forms an electrically conductive, thermal insulator which is much more electrically-conductive, especially at high temperatures, than other insulators. This effect is due to the number of paths and the continuous flow of the paths the electrical energy can traverse. Further, forming the electrically-conductive thermal insulator in the above preferred manner is superior to other forming methods (e.g., forming embedded wires or a metal mesh in an insulative coating) in that the electrically-conductive thermal insulator can be manufactured at a much lower cost and have a lower density and therefore a lower weight than a similar solid material of the same size.

A preferred embodiment of an electrically-conductive thermal insulator is described and illustrated herein. While a multi-celled electrically-conductive base material has been described, and it is preferable that the multi-celled, electrically-conductive base material be formed as an open-celled, electrically-conductive base material, and more preferably, as an open-celled metallic foam material, it will be appreciated by those skilled in the art that the electrically-conductive base material may be other than an open-celled metallic foam material so long as the base material defines a plurality of cells throughout (preferably interconnected cells) and so long as the base material is electrically conductive. These materials include but are not limited to electrically-conductive materials other than metals or metal composites and woven or interlocking metallic fiber materials defining interconnected cells or voids throughout. Such materials may be fabricated into a desired shape or may be purchased in prefabricated sheets and molded to a desired shape. However, the open-celled metallic foam material has an additional advantage over the interwoven metallic materials in certain applications as it may be substantially more rigid than other forms of open-celled, electrically-conductive base materials. Further, while particular polymer-based thermally-insulating materials have been disclosed for use in thermally insulating the electrically-conductive base material, it will be appreciated by those skilled in the art that other types of thermally-insulating materials may be applied so long as they are of the proper viscosity such that they can flow throughout the cells in the open-celled electrically-conductive base material and so long as they are curable to form a durable, electrically-insulating coating which can withstand extreme aerothermal environments. Further, while it may be preferable that the electrically-conductive base material be substantially malleable in certain applications, it will be appreciated by those skilled in the art that in other applications, it may be preferable that the electrically-conductive base material be substantially rigid. Moreover, while it is preferable that all cells be at least substantially filled with the thermally-insulating material, it will be appreciated by those skilled in the art that some of the cells may be only partially filled with the thermally-insulating material or may not contain any of the thermally-insulating material. Further, while a particular embodiment of the invention has been described, it is not intended that the invention be limited thereto, as it is intended that the invention be as broad in scope as the art will allow and that the specification be read likewise. Thus, while a particular application for the invention has been described, it will be understood by those skilled in the art that there may be other applications for the invention. It will also be appreciated by those skilled in the art that yet other modifications could be made to the provided invention without deviating from the spirit and scope of the invention as claimed.

What is claimed is:

1. An electrically-conductive thermal insulator comprising:
an electrically-conductive material defining a plurality of cells interspersed throughout the electrically-conductive material; and
a cured thermally-insulating material, said thermally-insulating material substantially coating said electrically-conductive material and substantially filling at least some of said plurality of cells in said electrically-conductive material.

2. An electrically-conductive thermal insulator as claimed in claim 1, wherein said plurality of cells is substantially interconnected.

3. An electrically-conductive thermal insulator as claimed in claim 1, wherein said electrically-conductive material is an electrically-conductive open-celled metallic foam material.

4. An electrically-conductive thermal insulator as claimed in claim 1, wherein said electrically-conductive material is formed of a plurality of substantially interconnected electrically-conductive ligaments.

5. An electrically-conductive thermal insulator as claimed in claim 1, wherein said thermally-insulating material is a polymer-based thermally-insulating material.

6. An electrically-conductive thermal insulator as claimed in claim 5, wherein the polymer-based insulating material is a silicone-based thermally-insulating material.

7. An electrically-conductive thermal insulator as claimed in claim 5, wherein the polymer-based thermal insulating material ha s glass microballoons dispersed substantially throughout.

8. An electrically-conductive thermal insulator as claimed in claim 5, wherein the polymer-based thermal insulating material has ceramic microballoons dispersed substantially throughout.

9. A method of forming an electrically-conductive thermal insulator comprising the steps of:
coating an electrically-conductive base material defining a plurality of interconnected cells throughout with a curable thermally-insulating material such that said curable thermally-insulating material substantially coats said electrically-conductive base material and substantially fills at least some of said plurality of cells in said electrically-conductive base material; and then
curing said thermally-insulating material.

10. A method according to claim 9, further comprising the step of: prior to coating, forming said electrically-conductive base material into a desired shape.

11. A method of forming an electrically-conductive thermal insulator comprising:
interconnecting a plurality of electrically-conductive ligaments such that the plurality of interconnected, electrically-conductive ligaments form a structure defining a plurality of substantially interconnected cells throughout and said plurality of interconnected electrically-conductive ligaments form a plurality of electrically conductive pathways;
applying a thermally-insulating material to said structure, said thermally-insulating material being curable and having a viscosity when uncured such that said uncured thermally-insulating material substantially coats said structure and substantially flows throughout said structure substantially filling a plurality of said plurality of substantially interconnected cells; and then
curing said thermally-insulating material.
